(19) United States
(12) Patent Application Publication
(10) Pub. No.: US 2026/0282655 A1
(43) Pub. Date: Sep. 17, 2026

(54) DISPLAY DEVICE AND ELECTRONIC DEVICE

(71) Applicant: Samsung Display Co., Ltd., Yongin-si (KR)

(72) Inventors: Kyung Bae KIM, Yongin-si (KR); Jang Mi KANG, Yongin-si (KR); Kyeong Min PARK, Yongin-si (KR); Gyung Soon PARK, Yongin-si (KR)

(21) Appl. No.: 19/558,150

(22) Filed: Mar. 5, 2026

(30) Foreign Application Priority Data
Mar. 17, 2025 (KR) 10-2025-0033708

(51) Int. Cl. H10K 59/121; H10D 86/40; H10D 86/60; H10K 59/131

(52) U.S. Cl. CPC H10K 59/1213; H10D 86/423; H10D 86/441; H10D 86/60; H10K 59/131

(57) ABSTRACT

A display device includes: a substrate having a display area and a non-display area; and a driver circuit layer, a pixel circuit layer and a display element layer arranged on the substrate, wherein the driver circuit layer is connected to a pixel circuit of the pixel circuit layer, wherein the pixel circuit of the pixel circuit layer is connected to a light-emitting element of the display element layer, and wherein the driver circuit layer, the pixel circuit layer and the display element layer are arranged on the display area of the substrate such that they overlap each other in a plan view.

### CROSS-REFERENCE TO RELATED APPLICATION

The present application claims priority to and the benefit of Korean Patent Application No. 10-2025-0033708, filed on Mar. 17, 2025, in the Korean Intellectual Property Office, the entire disclosure of which is incorporated herein by reference.

### BACKGROUND

### 1. Field

Aspects of some embodiments of the present disclosure relate to a display device and an electronic device including the same.

### 2. Description of the Related Art

An organic light-emitting display apparatus includes display elements having luminance that may vary depending on electric current, for example, organic light-emitting diodes.

The above information disclosed in this Background section is only for enhancement of understanding of the background and therefore the information discussed in this Background section does not necessarily constitute prior art.

### SUMMARY

Aspects of some embodiments of the present disclosure relate to a display device and an electronic device including the same, and for example, to a display device and an electronic device in which a display area can be relatively expanded, and short-channel effects can be prevented or reduced while enabling a high driving speed of a driver circuit.

Aspects of some embodiments of the present disclosure include a display device and an electronic device in which a display area can be relatively expanded, and short-channel effects can be prevented or reduced while enabling a high driving speed of a driving circuit.

According to some embodiments of the present disclosure, a display device includes: a substrate having a display area and a non-display area; and a driver circuit layer, a pixel circuit layer and a display element layer arranged on the substrate. According to some embodiments, the driver circuit layer may be connected to a pixel circuit of the pixel circuit layer. According to some embodiments, the pixel circuit of the pixel circuit layer may be connected to a light-emitting element of the display element layer. According to some embodiments, the driver circuit layer, the pixel circuit layer and the display element layer may be arranged on the display area of the substrate such that they overlap one another in a direction perpendicular to an extension direction of the substrate.

According to some embodiments of the present disclosure, an electronic device includes a display device providing a display screen. According to some embodiments, the display device may include: a substrate having a display area and a non-display area; and a driver circuit layer, a pixel circuit layer and a display element layer arranged on the substrate. According to some embodiments, the driver circuit layer may be connected to a pixel circuit of the pixel circuit layer. According to some embodiments, the pixel circuit of the pixel circuit layer may be connected to a light-emitting element of the display element layer. According to some embodiments, the driver circuit layer, the pixel circuit layer and the display element layer may be arranged on the display area of the substrate such that they overlap one another in a direction perpendicular to an extension direction of the substrate.

According to some embodiments of the present disclosure, a display area can be relatively expanded, and short-channel effects can be prevented or reduced while enabling a high driving speed of a driving circuit.

For example, driver circuits and pixels may be formed in a vertical stack form or arrangement in the display area, and the driver circuit and pixels include oxide transistors. Accordingly, the display area can be relatively expanded, and short-channel effects can be prevented or reduced while ensuring a high driving speed of the driver circuits.

The characteristics of embodiments according to the present disclosure are not limited to the above-described characteristics and other characteristics which are not described herein will become apparent to those skilled in the art from the following description.

### BRIEF DESCRIPTION OF THE DRAWINGS

The above and other aspects and features of embodiments according to the present disclosure will become more apparent by describing in more detail aspects of some embodiments thereof with reference to the attached drawings, in which:

FIG. 1 is an exploded, perspective view showing a display device according to some embodiments of the present disclosure.

FIG. 2 is a block diagram showing a display device according to some embodiments of the present disclosure.

FIG. 3 is a view showing an example of a layout of a display panel according to some embodiments of the present disclosure.

FIGS. 4 and 5 are layout diagrams showing examples of the display area of FIG. 3.

FIG. 6 is a cross-sectional view of a display panel of a display device according to some embodiments of the present disclosure.

FIG. 7 is a cross-sectional view of a display panel of a display device according to some embodiments of the present disclosure.

FIG. 8 is a plan view of a display device according to some embodiments of the present disclosure.

FIG. 9 is a cross-sectional view of a display panel of a display device according to some embodiments of the present disclosure.

FIG. 10 is a block diagram of an electronic device according to some embodiments of the present disclosure.

FIGS. 11, 12 and 13 are views showing electronic devices according to some embodiments of the present disclosure.

### DETAILED DESCRIPTION

Aspects of some embodiments of the present disclosure will now be described more fully hereinafter with reference to the accompanying drawings, in which aspects of some embodiments of the invention are shown. This invention may, however, be embodied in different forms and should not be construed as limited to the embodiments set forth herein. Rather, these embodiments are provided so that this disclosure will be thorough and complete, and will fully convey the scope of the invention to those skilled in the art.

It will also be understood that when a layer is referred to as being “on” another layer or substrate, it can be directly on the other layer or substrate, or intervening layers may also be present. The same reference numbers indicate the same components throughout the specification. In the attached figures, the thickness of layers and regions is exaggerated for clarity.

Although the terms “first”, “second”, etc. may be used herein to describe various elements, these elements, should not be limited by these terms. These terms may be used to distinguish one element from another element. Thus, a first element discussed below may be termed a second element without departing from teachings of one or more embodiments. The description of an element as a “first” element may not require or imply the presence of a second element or other elements. The terms “first”, “second”, etc. may also be used herein to differentiate different categories or sets of elements. For conciseness, the terms “first”, “second”, etc. may represent “first-category (or first-set)”, “second-category (or second-set)”, etc., respectively.

Features of various embodiments of the present disclosure may be combined partially or totally. As will be clearly appreciated by those skilled in the art, technically various interactions and operations are possible. Various embodiments can be practiced individually or in combination.

Hereinafter, aspects of some embodiments will be described in more detail with reference to the accompanying drawings.

Hereinafter, aspects of some embodiments of the present disclosure will be described in more detail with reference to the accompanying drawings.

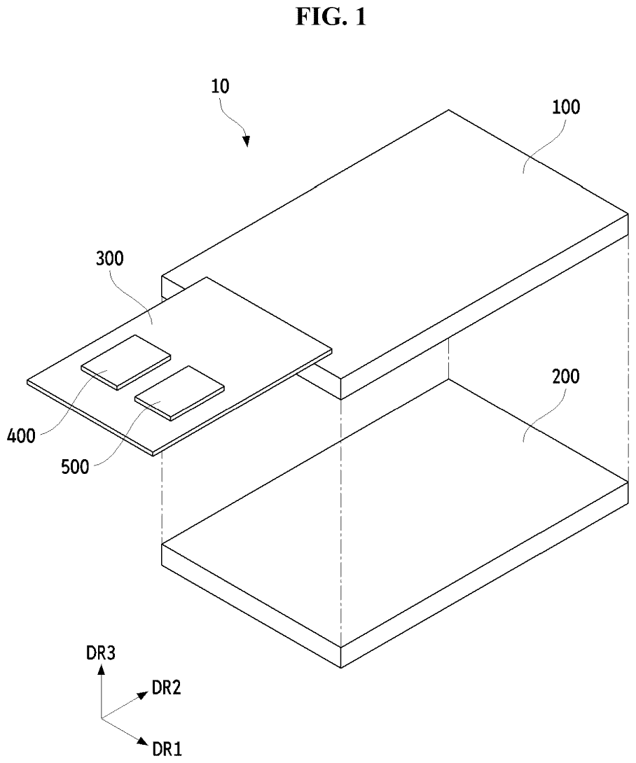

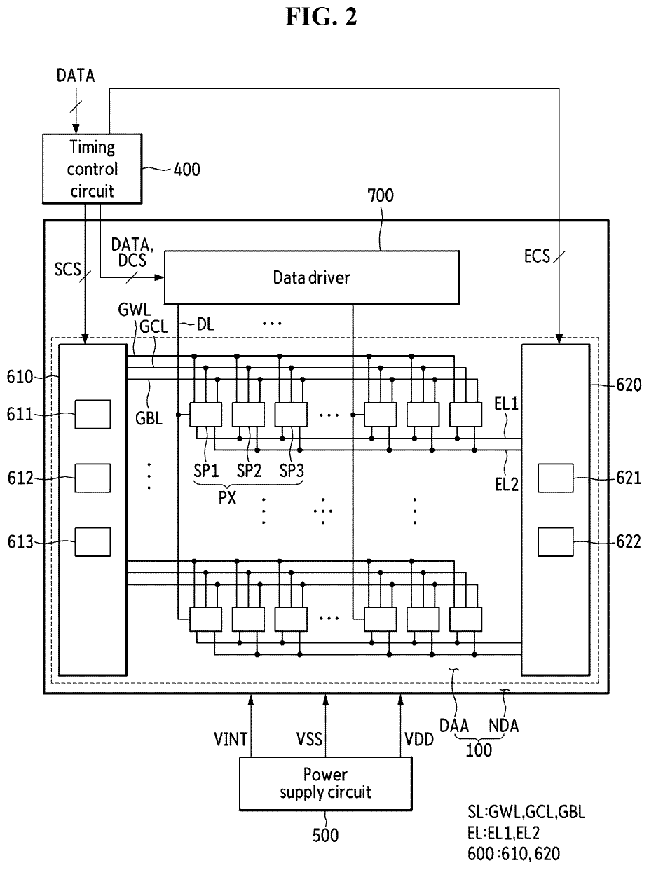

FIG. 1 is an exploded, perspective view of a display device according to some embodiments of the present disclosure. FIG. 2 is a block diagram showing a display device according to some embodiments of the present disclosure.

Referring to FIGS. 1 and 2, the display device 10 according to some embodiments displays moving images (e.g., video images) or still images (e.g., static images). The display device 10 according to some embodiments may be employed by or incorporated into portable electronic devices such as a mobile phone, a smart phone, a tablet PC, a mobile communications terminal, an electronic notebook, an electronic book, a portable multimedia player (PMP), a navigation device and an ultra mobile PC (UMPC). For example, the display device 10 according to some embodiments of the present disclosure may be used as a display unit of a television, a laptop computer, a monitor, an electronic billboard, or the Internet of Things (IOT). Alternatively, the display device 10 according to some embodiments of the present disclosure may be applied to a smart watch, a watch phone, or a head-mounted display (HMD) for implementing virtual reality and augmented reality.

According to some embodiments, the display device 10 includes a display panel 100, a heat dissipation layer 200, a circuit board 300, a timing control circuit 400, and a power supply circuit 500, although embodiments according to the present disclosure are not limited thereto, and the display device 10 may include additional components.

The display panel 100 may have a shape similar to a rectangular shape when viewed from the top (e.g., in a plan view). For example, the display panel 100 may have a shape similar to a rectangle having shorter sides in the first direction DR1 and longer sides in the second direction DR2 intersecting the first direction DR1 when viewed from the top. In the display panel 100, the corners where the shorter sides in the first direction DR1 meet the longer sides in the second direction DR2 may be rounded with a curvature (e.g., a set or predetermined curvature) or may be a right angle. The shape of the display panel 100 when viewed from the top (e.g., in a plan view) is not limited to a rectangular shape, but may be formed in a shape similar to other polygonal shapes, a circular shape, an elliptical shape, or an irregular shape. The shape of the display device 10 may follow the shape of the display panel 100 when viewed from the top (e.g., in a plan view), but the embodiments of the present disclosure are not limited thereto.

The display panel 100 may include a plurality of pixels PX, a plurality of scan lines SL, a plurality of emission control lines EL, a plurality of data lines DL, a pixel driver 600, and a data driver 700. The pixel driver 600 may include a scan driver 610 and an emission driver 620. The display panel 100 may be divided into a display area DAA where images are displayed, and a non-display area NDA where no image is displayed as shown in FIG. 2. According to some embodiments, the non-display area NDA may surround (e.g., in a periphery or outside a footprint of) the display area DAA.

The plurality of pixels PX may be arranged in the display area DAA. The pixels PX may be arranged in a matrix (e.g., a plurality of rows and columns) extending in the first direction DR1 and the second direction DR2. The scan lines SL and the emission control lines EL may extend in the first direction DR1 and may be arranged in the second direction DR2. The data lines DL may extend in the second direction DR2 and may be arranged in the first direction DR1.

The plurality of scan lines SL includes a plurality of write scan lines GWL, a plurality of control scan lines GCL, and a plurality of bias scan lines GBL. The plurality of emission control lines EL includes a plurality of first emission control lines EL1 and a plurality of second emission control lines EL2.

The plurality of pixels PX includes a plurality of sub-pixels SP1, SP2 and SP3. The sub-pixels SP1, SP2 and SP3 include transistors.

Each of the sub-pixels SP1, SP2 and SP3 may be connected to one of the write scan lines GWL, one of the control scan lines GCL, one of the bias scan lines GBL, one of the first emission control lines EL1, one of the second emission control lines EL2, and one of the data lines DL. Each of the sub-pixels SP1, SP2 and SP3 may receive the data voltage from the data line DL according to the write scan signal from the write scan line GWL, and may allow the light-emitting elements to emit light according to the data voltage.

The pixels PX and the pixel driver 600 may be arranged in the display area DAA. For example, the plurality of pixels PX, the scan driver 610 and the emission driver 620 may be arranged in the display area DAA.

The scan driver 610 may include a plurality of scan transistors, and the emission driver 620 may include a plurality of emission transistors.

The scan driver 610 may include a write scan signal output unit 611, a control scan signal output unit 612, and a bias scan signal output unit 613. Each of the write scan signal output unit 611, the control scan signal output unit 612 and the bias scan signal output unit 613 may receive a scan timing control signal SCS from the timing control circuit 400. The write scan signal output unit 611 may generate write scan signals according to the scan timing control signal SCS from the timing control circuit 400 and sequentially output them to the write scan lines GWL. The control scan signal output unit 612 may generate control scan signals according to the scan timing control signal SCS and sequentially output them to the control scan lines GCL. The bias scan signal output unit 613 may generate bias scan signals according to the scan timing control signal SCS and sequentially output them to the bias scan lines EBL.

The emission driver 620 may include a first emission control driver 621 and a second emission control driver 622. Each of the first emission control driver 621 and the second emission control driver 622 may receive an emission timing control signal ECS from the timing control circuit 400. The first emission control driver 621 may generate first emission control signals according to the emission timing control signal ECS and sequentially output them to the first emission control lines EL1. The second emission control driver 622 may generate second emission control signals according to the emission timing control signal ECS and sequentially output them to the second emission control lines EL2.

The data driver 700 may be located in the non-display area NDA. The data driver 700 may include a plurality of data transistors. The data driver 700 may receive digital video data DATA and a data timing control signal DCS from the timing control circuit 400. The data driver 700 converts the digital video data DATA into analog data voltages according to the data timing control signal DCS and outputs them to the data lines DL. In doing so, the sub-pixels SP1, SP2 and SP3 are selected by the write scan signal from the scan driver 610, and data voltages may be applied to the selected sub-pixels SP1, SP2 and SP3.

The heat dissipation layer 200 may overlap with the display panel 100 in the third direction DR3, which is the thickness direction of the display panel 100. The heat dissipation layer 200 may be located on one surface of the display panel 100, e.g., on the rear surface. The heat dissipation layer 200 serves to release heat generated in the display panel 100. The heat dissipation layer 200 may include a metal layer such as graphite, silver (Ag), copper (Cu), or aluminum (Al), or any other suitable conductive material having a high thermal conductivity.

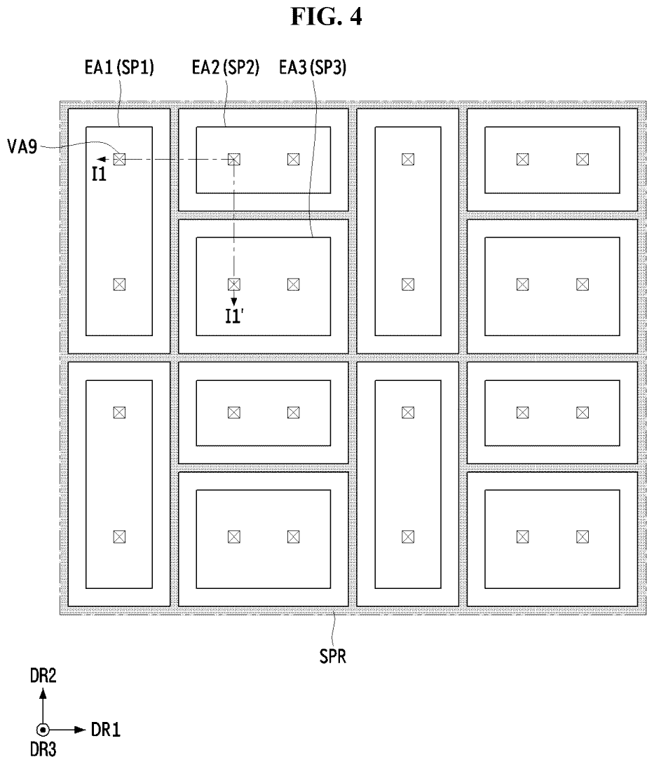

The circuit board 300 may be electrically connected to a plurality of first pads PD1 (see FIG. 4) of a first pad area PDA1 (see FIG. 4) of the display panel 100 using a conductive adhesive member such as an anisotropic conductive film. The circuit board 300 may be a flexible printed circuit board made of a flexible material, or a flexible film.

Although the circuit board 300 is unfolded in the example shown in FIG. 1, the circuit board 300 may be bent. When the circuit board 300 is bent, one end of the circuit board 300 may be located on the rear surface of the display panel 100 and/or the rear surface of the heat dissipation layer 200. The other end of the circuit board 300 may be connected to a plurality of first pads PD1 (see FIG. 4) of the first pad area PDA1 (see FIG. 4) of the display panel 100 using a conductive adhesive material. One end of the circuit board 300 may be opposite to the other end of the circuit board 300.

The timing control circuit 400 may receive digital video data and timing signals from the outside. The timing control circuit 400 may generate a scan timing control signal SCS, an emission timing control signal ECS, and a data timing control signal DCS for controlling the display panel 100 in response to the timing signals. The timing control circuit 400 may output the scan timing control signal SCS to the scan driver 610 and output the emission timing control signal ECS to the emission driver 620. The timing control circuit 400 may output the digital video data and the data timing control signal DCS to the data driver 700.

A power supply circuit 500 may generate a plurality of panel driving voltages in response to a supply voltage from the outside. For example, the power supply circuit 500 may generate a first supply voltage VSS, a second supply voltage VDD, and a third supply voltage VINT to apply them to the display panel 100.

Each of the timing control circuit 400 and the power supply circuit 500 may be implemented as an integrated circuit (IC) and attached to a surface of the circuit board 300. The scan timing control signal SCS, the emission timing control signal ECS, the digital video data DATA and the data timing control signal DCS from the timing control circuit 400 may be supplied to the display panel 100 through the circuit board 300. The first supply voltage VSS, the second supply voltage VDD and the third supply voltage VINT of the power supply circuit 500 may be supplied to the display panel 100 through the circuit board 300.

Alternatively, each of the timing control circuit 400 and the power supply circuit 500 may be located in the non-display area NDA of the display panel 100, similarly to the data driver 700. In this instance, the timing control circuit 400 may include a plurality of timing transistors, and each power supply circuit 500 may include a plurality of power transistors. Each of the timing control circuit 400 and the power supply circuit 500 may be located between the data driver 700 and the first pad area PDA1 (see FIG. 4).

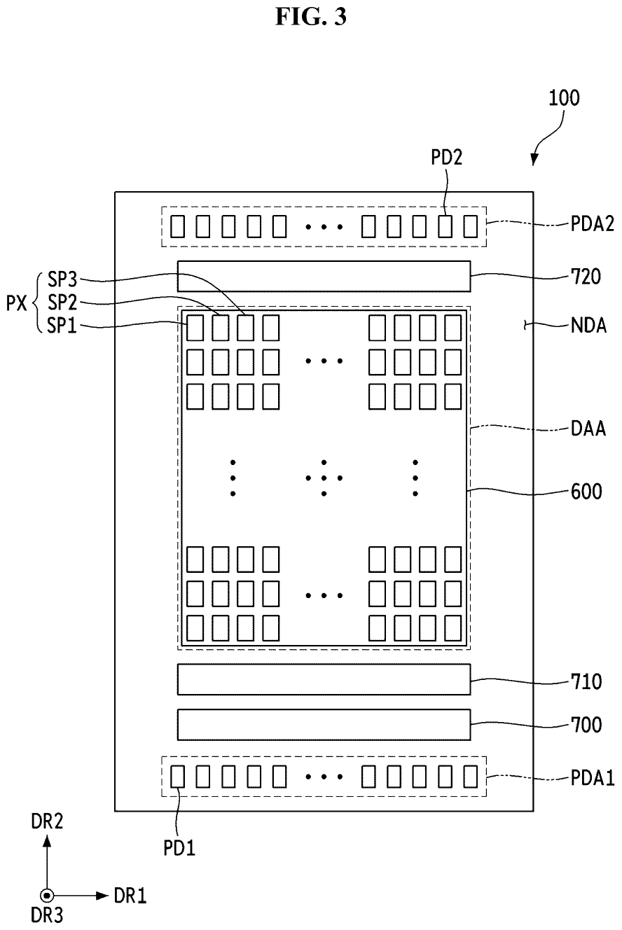

FIG. 3 is a view showing an example of a layout of a display panel according to some embodiments of the present disclosure.

Referring to FIG. 3, in the display area DAA of the display panel 100 according to some embodiments, a plurality of pixels PX arranged in a matrix form or arrangement (e.g., in a plurality of rows and columns) and the pixel driver 600 may be located.

The pixel driver 600 may include the scan driver 610 and the emission driver 620 described above. The pixel driver 600 may overlap with the pixels PX (or sub-pixels). For example, in the display area DAA, the scan driver 610 and the emission driver 620 of the pixel driver 600 may overlap the pixels PX.

In the non-display area NDA of the display panel 100, the data driver 700, a first distribution circuit 710, a second distribution circuit 720, a first pad area PDA1, and a second pad area PDA2 may be arranged.

The first pad area PDA1 may include a plurality of first pads PD1 connected to pads or bumps of the circuit board 300 through a conductive adhesive member. The first pad area PDA1 may be located on a third side of the display area DAA. For example, the first pad area PDA1 may be located on one side of the display area DAA in the second direction DR2. The first pad area PDA1 may be located on the outer side of the data driver 700 in the second direction DR2. For example, the first pad area PDA1 may be located closer to the edge of the display panel 100 than the data driver 700 is.

The second pad area PDA2 may include a plurality of second pads PD2 which is test pads for testing whether the display panel 100 operates normally. The plurality of second pads PD2 may be connected to a jig or a probe pin during a test process, or may be connected to a circuit board for testing. The circuit board for testing may be a printed circuit board made of a rigid material or a flexible printed circuit board made of a flexible material.

The second pad area PDA2 may be located on a fourth side of the display area DAA. For example, the second pad area PDA2 may be located on the opposite side of the display area DAA in the second direction DR2. The second pad area PDA2 may be located on the outer side of the second distribution circuit 720 in the second direction DR2. That is to say, the second pad area PDA2 may be located closer to the edge of the display panel 100 than the second distribution circuit 720.

The first distribution circuit 710 distributes data voltages applied via the first pad area PDA1 to a plurality of data lines DL. For example, the first distribution circuit 710 may divide the data voltages applied via one first pad PD1 of the first pad area PDA1 into P data lines DL, thereby relatively reducing the number of the plurality of first pads PD1, where P is a positive integer equal to or greater than two. The first distribution circuit 710 may be located on the third side of the display area DAA of the display panel 100. For example, the first distribution circuit 710 may be located on one side of the display area DAA in the second direction DR2. That is to say, the first distribution circuit 710 may be located on the lower side of the display area DAA. The first distribution circuit 710 may include a plurality of first distribution transistors.

The second distribution circuit 720 distributes signals applied through the second pad area PDA2 to the scan driver 610, the emission driver 620, and the data lines DL. The second pad area PDA2 and the second distribution circuit 720 may be elements to test the operation of each of the pixels PX in the display area DAA. The second distribution circuit 720 may be located on a fourth side of the display area DAA of the display panel 100. For example, the second distribution circuit 720 may be located on the opposite side of the display area DAA in the second direction DR2. That is to say, the second distribution circuit 720 may be located on the upper side of the display area DAA. The second distribution circuit 720 may include a plurality of second distribution transistors.

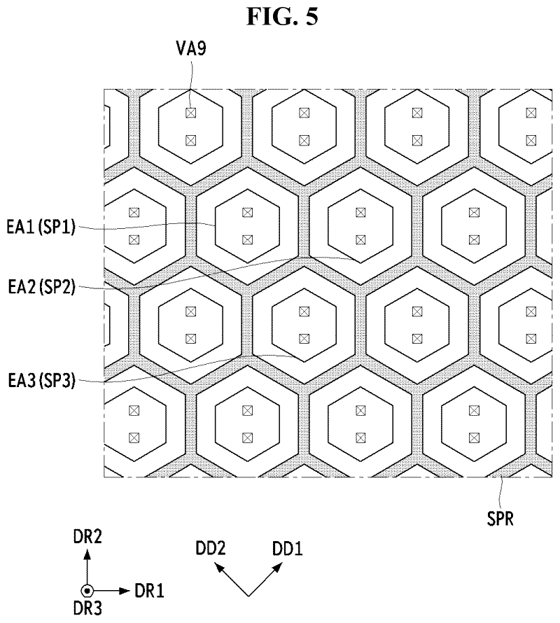

FIGS. 4 and 5 are layout diagrams showing examples of the display area of FIG. 3.

Referring to FIGS. 4 and 5, each of the plurality of pixels PX may include a first emission area EA1 that is the emission area of the first sub-pixel SP1, a second emission area EA2 that is the emission area of the second sub-pixel SP2, and a third emission area EA3 that is the emission area of the third sub-pixel SP3.

Each of the first emission area EA1, the second emission area EA2 and the third emission area EA3 may have a polygonal shape, a circular shape, an elliptical shape, or an irregular shape when viewed from the top (e.g., in a plan view).

The maximum length of the first emission area EA1 in the first direction DR1 may be smaller than the maximum length of the second emission area EA2 in the first direction DR1 and the maximum length of the third emission area EA3 in the first direction DR1. The maximum length of the second emission area EA2 in the first direction DR1 may be substantially equal to the maximum length of the third emission area EA3 in the first direction DR1.

The maximum length (e.g., the longest length) of the first emission area EA1 in the second direction DR2 may be greater than the maximum length of the second emission area EA2 in the second direction DR2 and the maximum length of the third emission area EA3 in the second direction DR2. The maximum length of the second emission area EA2 in the second direction DR2 may be greater than the maximum length of the third emission area EA3 in the second direction DR2. The maximum length of the first emission area EA1 in the second direction DR2 may be smaller than the maximum length of the second emission area EA2 in the second direction DR2.

The first emission area EA1, the second emission area EA2 and the third emission area EA3 may have a hexagonal shape consisting of six straight lines as shown in FIGS. 4 and 5 when viewed from the top. It should be understood, however, that the embodiments of the present disclosure are not limited thereto. The first emission area EA1, the second emission area EA2 and the third emission area EA3 may have a polygonal shape other than a hexagon, a circular shape, an elliptical shape, or an irregular shape when viewed from the top.

As shown in FIG. 4, in each of the plurality of pixels PX, the first emission area EA1 and the second emission area EA2 may be adjacent to each other in the first direction DR1. In addition, the first emission area EA1 and the third emission area EA3 may be adjacent to each other in the first direction DR1. In addition, the second emission area EA2 and the third emission area EA3 may be adjacent to each other in the second direction DR2. The first emission area EA1, the second emission area EA2 and the third emission area EA3 may have different areas.

Alternatively, as shown in FIG. 5, the first emission area EA1 and the second emission area EA2 may be adjacent to each other in the first direction DR1, the second emission area EA2 and the third emission area EA3 may be adjacent to each other in a first diagonal direction DD1, and the first emission area EA1 and the third emission area EA3 may be adjacent to each other in a second diagonal direction DD2. The first diagonal direction DD1 refer to a direction between the first direction DR1 and the second direction DR2, and refers to a direction inclined by 45 degrees relative to the first direction DR1 and the second direction DR2. The second diagonal direction DD2 may be orthogonal to the first diagonal direction DD1.

The first sub-pixel SP1 may output the first light that has passed through the first color filter CF1 from among the lights output from the first emission area EA1, the second sub-pixel SP2 may output the second light that has passed through the second color filter CF2 from among the lights output from the second emission area EA2, and the third sub-pixel SP3 may output the third light that has passed through the third color filter CF3 from among the lights output from the third emission area EA3.

The first light, the second light and the third light described above may be lights of different wavelength ranges. For example, one of the first to third lights may be light in a blue wavelength range, another one may be light in a green wavelength range, and the other one may be light in a red wavelength range. The blue wavelength range may refer that the main peak wavelength of light lies in the wavelength range of 370 nanometers (nm) to 480 nm (or approximately 370 nm to 480 nm), the green wavelength range may refer that the main peak wavelength of light lies in the wavelength range of 480 nm to 560 nm (or approximately 480 nm to 560 nm), and the red wavelength range may refer to that the main peak wavelength of light lies in the wavelength range of 600 nm to 750 nm (or approximately 600 nm to 750 nm).

Although each of the plurality of pixels PX includes three emission areas EA1, EA2 and EA3 in the example shown in FIGS. 4 and 5, the embodiments of the present disclosure are not limited thereto. For example, each of the plurality of pixels PX may include four emission areas.

In addition, the layout of the emission areas of the plurality of pixels PX is not limited to that shown in FIGS. 4 and 5. For example, the emission areas of the plurality of pixels PX may have a stripe structure in which the emission areas are arranged in the first direction DR1, a PenTile® matrix in which the emission areas have a diamond arrangement, or a hexagonal structure in which emission areas having a hexagonal shape when viewed from the top (e.g., in a plan view) are arranged as shown in FIG. 5.

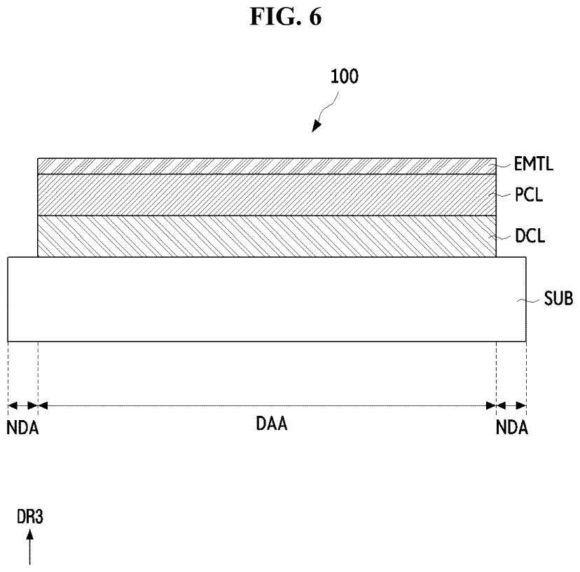

FIG. 6 is a cross-sectional view of a display panel 100 of a display device 10 according to some embodiments of the present disclosure. For example, FIG. 6 may be a cross-sectional view of the display panel 100 of FIG. 3.

The display panel 100 according to some embodiments may include a semiconductor substrate SUB, a driver circuit layer DCL, a pixel circuit layer PCL and a display element layer EMTL, as shown in FIG. 6, although embodiments according to the present disclosure are not limited thereto, and according to some embodiments the display panel 100 may include additional layers or components.

The driver circuit layer DCL, the pixel circuit layer PCL and the display element layer EMTL may be arranged on the display area DAA of the semiconductor substrate SUB so that they overlap one another in a direction perpendicular to a direction in which the semiconductor substrate SUB is extended (e.g., the first direction DR1 and the second direction DR2). That is, the driver circuit layer DCL, the pixel circuit layer PCL, and the display element layer EMTL overlap each other in a plan view (e.g., a view perpendicular to a display surface of the display panel 100).

The pixel circuit layer PCL may be located between the semiconductor substrate and the driver circuit layer DCL.

The driver circuit layer DCL may be located between the pixel circuit layer PCL and the display element layer EMTL.

The semiconductor substrate SUB may be a wafer substrate.

The driver circuit layer DCL may be placed on the display area DAA of the semiconductor substrate SUB. The driver circuit layer DCL may include the pixel driver 600 described above. For example, the driver circuit layer DCL may include a scan driver 610 and an emission driver 620. In other words, the driver circuit layer DCL may include a plurality of scan transistors and a plurality of emission transistors.

The pixel circuit layer PCL may be placed on the driver circuit layer DCL. For example, the pixel circuit layer PCL may be arranged on the driver circuit layer DCL in the display area DAA of the semiconductor substrate SUB. The pixel circuit layer PCL may include a plurality of pixel transistors. Each of the plurality of sub-pixels may include a plurality of pixel transistors, and thus the plurality of pixel transistors may be arranged in the pixel circuit layer PCL. The pixel circuits may be connected to a scan transistor and an emission transistor of the driver circuit layer DCL.

The display element layer EMTL may be placed on the pixel circuit layer PCL. For example, the display element layer EMTL may be located on the driver circuit layer DCL in the display area DAA of the semiconductor substrate SUB. Each of the plurality of sub-pixels SP1, SP2 and SP3 may include a plurality of light-emitting elements, and the plurality of light-emitting elements may be arranged in the display element layer EMTL. One sub-pixel (e.g., sub-pixel SP1) may include a pixel circuit of the pixel circuit layer PCL and a light-emitting element connected to the pixel circuit. The light-emitting element may include a first electrode (e.g., an anode electrode), an emission (e.g., an organic emissive layer), and a second electrode (e.g., a cathode electrode).

According to some embodiments, the driver circuit layer DCL, the pixel circuit layer PCL and the display element layer EMTL overlap one another in the display area DAA, and accordingly the size of the non-display area NDA may be relatively reduced. In addition, the driver circuit layer DCL is located in the display area DAA instead of the non-display area NDA, the spare area of the non-display area NDA may be relatively increased, and the display area DAA may be relatively expanded to the spare area.

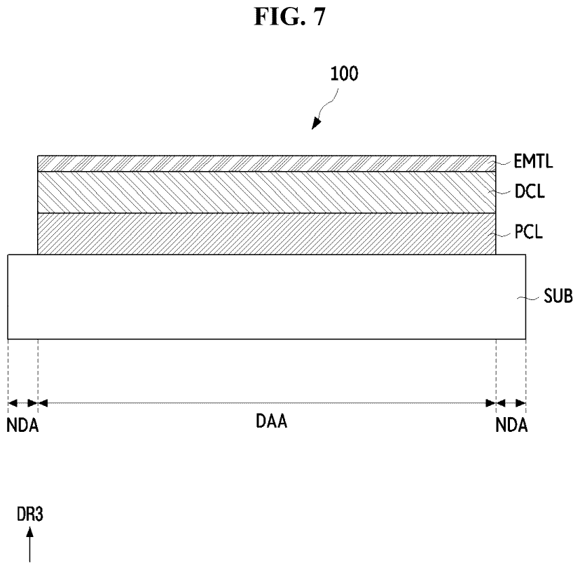

FIG. 7 is a cross-sectional view of a display panel 100 of a display device 10 according to some embodiments of the present disclosure. For example, FIG. 7 may be a cross-sectional view of the display panel 100 of FIG. 3.

The display panel 100 of FIG. 7 is substantially identical to the display panel 100 of FIG. 6 except for positions of a driver circuit layer DCL and a pixel circuit layer PCL; and, therefore, some redundant descriptions may be omitted.

The display panel 100 according to some embodiments may include a pixel circuit layer PCL, a driver circuit layer DCL and a display element layer EMTL arranged on a display area DAA of a semiconductor substrate SUB, as shown in FIG. 7. The driver circuit layer DCL may be located on the pixel circuit layer PCL. For example, the driver circuit layer DCL may be placed between the pixel circuit layer PCL and the display element layer EMTL, and the pixel circuit layer PCL may be placed between the semiconductor substrate SUB and the driver circuit layer DCL.

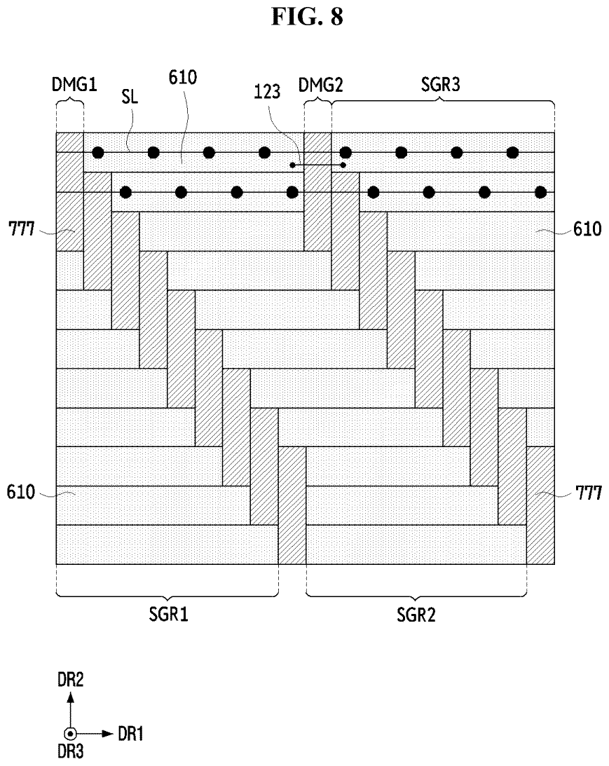

FIG. 8 is a plan view of a display device 10 according to some embodiments of the present disclosure.

As shown in FIG. 8, the driver circuit layer DCL may include a plurality of scan drivers 610 and a plurality of distribution circuits 777. The distribution circuits 777 may include at least one of the first distribution circuits 710 or the second distribution circuits 720 described above. For example, the distribution circuits 777 may include a plurality of first distribution circuits 710, a plurality of second distribution circuits 720, or a plurality of first distribution circuits 710 and a plurality of second distribution circuits 720.

The scan drivers 610 may be arranged along a diagonal direction. The scan drivers 610 may be divided into a plurality of scan groups. One scan group may include a plurality of scan drivers 610 arranged along the diagonal direction such that they are adjacent to one another. For example, FIG. 8 shows a first scan group SGR1, a second scan group SGR2, and a third scan group SGR3. The first scan group SGR1 may include a plurality of scan drivers 610 arranged adjacent to one another along the diagonal direction, the second scan group SGR2 may include a plurality of scan drivers 610 arranged adjacent to one another along the diagonal direction, and the third scan group SGR3 may include a plurality of scan drivers 610 arranged adjacent to one another along the diagonal direction.

Adjacent scan groups may be spaced apart from each other by a certain distance. For example, adjacent first scan group SGR1 and second scan group SGR2 may be spaced apart from each other by a distance, and adjacent second scan group SGR2 and third scan group SGR3 may be spaced apart from each other by a distance.

Among the scan drivers 610 arranged in different scan groups, the scan drivers 610 facing each other may be connected to each other. For example, when a scan driver 610 of the second scan group SGR2 is defined as a first scan driver, a scan driver 610 (hereinafter referred to as a second scan driver) of the third scan group SGR3 which faces the second scan driver 610 may be connected with each other through a connection line 123. A plurality of scan drivers 610 arranged in different scan groups and connected with one another through connection lines 123 may be connected to a single scan line SL. For example, a plurality of write scan signal output units 611 arranged in different scan groups and connected with one another through the connection lines 123 may be connected to a single write scan line GWL

Each scan driver 610 may include a plurality of scan transistors.

According to some embodiments, a voltage drop of a scan line SL can be relatively reduced by driving the scan line SL with a plurality of scan drivers 610.

The plurality of distribution circuits 777 may be arranged along the diagonal direction. The distribution circuits 777 may be divided into a plurality of distribution groups. One distribution group may include a plurality of distribution drivers 777 arranged adjacent to each other along the diagonal direction. For example, FIG. 8 shows a first distribution group DMG1 and a second distribution group DMG2. The first distribution group DMG1 may include a plurality of distribution circuits 777 arranged adjacently to each other along the diagonal direction, and the second distribution group DMG2 may include a plurality of distribution circuits 777 arranged adjacent to each other along the diagonal direction.

The distribution groups may be arranged between adjacent scan groups. For example, the second distribution group DMG2 may be arranged between the second scan group SGR2 and the third scan group SGR3. The plurality of distribution groups and the plurality of scan groups may be arranged alternately along the first direction DR1.

Adjacent distribution groups may be spaced apart from each other by a distance. For example, the first distribution group DMG1 and the second distribution group DMG2 adjacent to each other may be spaced apart from each other by a distance.

Each distribution circuit 777 may include a plurality of distribution transistors.

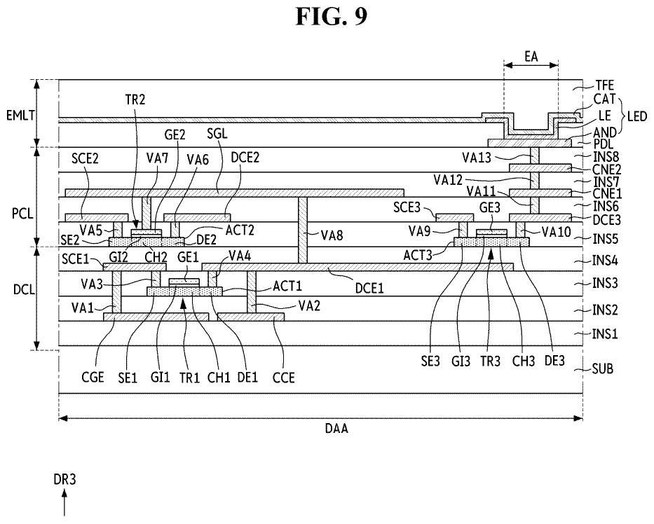

FIG. 9 is a cross-sectional view of a display panel 100 of a display device 10 according to some embodiments of the present disclosure.

The display panel 100 may include a semiconductor substrate SUB, a driver circuit layer DCL, and a display element layer EMTL, as shown in FIG. 9.

The driver circuit layer DCL may be placed on the display area DAA of the semiconductor substrate SUB. The driver circuit layer DCL may include a first transistor TR1 arranged on the display area DAA of the semiconductor substrate SUB. The first transistor TR1 may be arranged on a second insulating layer INS2 in the display area DAA.

The first transistor TR1 may be, for example, one of the scan transistor and the emission transistor described above. For example, the first transistor TR1 may be a scan transistor. The driver circuit layer DCL may include a plurality of first transistors TR1. The plurality of first transistors TR1 may include a scan transistor and an emission transistor.

The first transistor TR1 may be an oxide-based transistor (e.g., an oxide semiconductor transistor). For example, the first transistor TR1 may be an n-type oxide-based transistor. In other words, the first transistor TR1 may include an oxide semiconductor (or an oxide semiconductor material). Because the oxide semiconductor has high carrier mobility and low leakage current, the voltage drop is not large even if the driving time is long. For example, by virtue of the oxide semiconductor, the color change of an image due to a voltage drop is not significant even during low-frequency driving, allowing for low-frequency driving. Accordingly, the first transistor TR1 includes the oxide semiconductor material, so that it is possible to implement a display device 10 having relatively reduced power consumption while preventing or reducing leakage current.

The first transistor TR1 may include a first active layer ACT1, a first gate insulator GI1, a first gate electrode GE1, a first source electrode SE1, and a first drain electrode DE1. The first active layer ACT1 may include the first source electrode SE1, the first drain electrode DE1, and a first channel region CH1. The first gate insulator GI1 may be located between the first source electrode SE1 and the first drain electrode DE1. The first gate electrode GE1 may be located on the first gate insulator GI1 such that it overlaps with the first channel region CH1. The first active layer ACT1 may include an oxide. For example, the first active layer ACT1 may be a semiconductor layer that includes indium-gallium-zinc-oxide (IGZO) or indium-gallium-zinc-tin oxide (IGZTO).

The first source electrode SE1 of the first transistor TR1 may be connected to a first source connection electrode SCE1 through a third via electrode VA3, and the first source connection electrode SCE1 may be connected to a counter gate electrode CGE through a first via electrode VA1. The counter gate electrode CGE is arranged on the first insulating layer INS1 so that it overlaps with the first channel region CH1 of the first transistor TR1, thereby blocking external light from entering the first channel region CH1 of the first transistor TR1.

The first drain electrode DE1 of the first transistor TR1 may be connected to a first drain connection electrode DCE1 through a fourth via electrode VA4, and the first drain connection electrode DCE1 may be connected to a capacitor connection electrode CCE through a second via electrode VA2. According to some embodiments, the capacitor connection electrode CCE may be connected to a capacitor through a via electrode.

The counter gate electrode CGE and the capacitor connection electrode CCE may be arranged on the first insulating layer INS1. The first insulating layer INS1 may be located between the semiconductor substrate SUB and the second insulating layer INS2.

The first active layer ACT1 may be located on the second insulating layer INS2 such that it overlaps with the counter gate electrode CGE and the capacitor connection electrode CCE.

The first source connection electrode SCE1 and the first drain connection electrode DCE1 may be placed on a third insulating layer INS3.

The first via electrode VA1 may penetrate the second insulating layer INS2 and the third insulating layer INS3 to connect the first source connection electrode SCE1 with the counter gate electrode CGE.

The second via electrode VA2 may penetrate the second insulating layer INS2 and the third insulating layer INS3 to connect the first drain connection electrode DCE1 with the capacitor connection electrode CCE.

The third via electrode VA3 may penetrate the third insulating layer INS3 to connect the first source connection electrode SCE1 with the first source electrode SE1.

The fourth via electrode VA4 may penetrate the third insulating layer INS3 to connect the first drain connection electrode DCE1 with the first drain electrode DE1.

The pixel circuit layer PCL may be placed on the driver circuit layer DCL in the display area DAA. The pixel circuit layer PCL may include a second transistor TR2 and a third transistor TR3 arranged on the driver circuit layer DCL. For example, a pixel circuit of the pixel circuit layer PCL may include the second transistor TR2 and the third transistor TR3. In other words, the pixel circuit included in a sub-pixel may include a second transistor TR2 and a third transistor TR3. The second transistor TR2 and the third transistor TR3 may be arranged on a fourth insulating layer INS4 in the display area DAA.

The second transistor TR2 and the third transistor TR3 may be, for example, the pixel transistors described above. In other words, the pixel transistors may include the second transistor TR2 and the third transistor TR3. The second transistor TR2 and the third transistor TR3 may be connected with each other.

Each of the second transistor TR2 and the third transistor TR3 may be an oxide-based transistor (e.g., an oxide semiconductor transistor).

The second transistor TR2 may include a second active layer ACT2, a second gate insulator GI2, a second gate electrode GE2, a second source electrode SE2, and a second drain electrode DE2. The second active layer ACT2 may include the second source electrode SE2, the second drain electrode DE2, and a second channel region CH2. The second gate insulator GI2 may be located between the second source electrode SE2 and the second drain electrode DE2. The second gate electrode GE2 may be located on the second gate insulator GI2 such that it overlaps with the second channel region CH2. The second active layer ACT2 may include an oxide. For example, the second active layer ACT2 may be a semiconductor layer that includes indium-gallium-zinc-oxide (IGZO) or indium-gallium-zinc-tin oxide (IGZTO). Incidentally, the first source connection electrode SCE1 described above overlaps with the second channel region CH2 of the second transistor TR2, thereby blocking external light from entering the second channel region CH2 of the second transistor TR2.

The second gate electrode GE2 of the second transistor TR2 may be connected to a signal line SGL through a seventh via electrode VA7. The signal line SGL may be one of the scan lines SL and the emission control lines EL described above. For example, when the first transistor TR1 described above is a scan transistor, the signal line may be a scan line SL (e.g., line GWL). When the first transistor TR1 described above is an emission transistor, the signal line SGL may be an emission control line (e.g., line EL1). At this time, the second gate electrode GE2 of the second transistor TR2 may be connected to the first transistor TR1 of the driver circuit layer DCL via the signal line SGL. For example, the second gate electrode GE2 of the second transistor TR2 may be connected to the first drain electrode DE1 of the first transistor TR1 via the seventh via electrode VA7, the signal line SGL, an eighth via electrode VA8 and the first drain connection electrode DCE1. Accordingly, a driving signal (e.g., a write scan signal) from the first transistor TR1 may be provided to the second transistor TR2 (e.g., a pixel transistor) via the signal line (e.g., a write scan line GWL).

The second source electrode SE2 of the second transistor TR2 may be connected to the second source connection electrode SCE2 through the fifth via electrode VA5.

The second drain electrode DE2 of the second transistor TR2 may be connected to the second drain connection electrode DCE2 through a sixth via electrode VA6.

The second active layer ACT2 may be located on the fourth insulating layer INS4 such that it overlaps with the first source connection electrode SCE1.

The second source connection electrode SCE2 and the second drain connection electrode DCE2 may be placed on a fifth insulating layer INS5.

The fifth via electrode VA5 may penetrate the fifth insulating layer INS5 to connect the second source connection electrode SCE2 with the second source electrode SE2.

The sixth via electrode VA6 may penetrate the fifth insulating layer INS5 to connect the second drain connection electrode DCE2 with the second drain electrode DE2.

The seventh via electrode VA7 may penetrate the fifth insulating layer INS5 and the sixth insulating layer INS6 to connect the signal line SGL with the second gate electrode GE2.

The eighth via electrode VA8 may penetrate the fourth insulating layer INS4, the fifth insulating layer INS5 and the sixth insulating layer INS6 to connect the signal line SGL with the first drain connection electrode DCE1.

The third transistor TR3 may include a third active layer ACT3, a third gate insulator GI3, a third gate electrode GE3, a third source electrode SE3, and a third drain electrode DE3. The third active layer ACT3 may include the third source electrode SE3, the third drain electrode DE3, and a third channel region CH3. The third gate insulator GI3 may be located between the third source electrode SE3 and the third drain electrode DE3. The third gate electrode GE3 may be located on the third gate insulator GI3 such that it overlaps with the third channel region CH3. The third active layer ACT3 may include an oxide. For example, the third active layer ACT3 may be a semiconductor layer that includes indium-gallium-zinc-oxide (IGZO) or indium-gallium-zinc-tin oxide (IGZTO). Incidentally, the first drain connection electrode DCE1 described above overlaps with the third channel region CH3 of the third transistor TR3, thereby blocking external light from entering the third channel region CH3 of the third transistor TR3.

The third source electrode SE3 of the third transistor TR3 may be connected to the third source connection electrode SCE3 through a ninth via electrode VA9.

The third drain electrode DE3 of the third transistor TR3 may be connected to a third drain connection electrode DCE3 through a tenth via electrode VA10.

The third active layer ACT3 may be located on the fourth insulating layer INS4 such that it overlaps with the first drain connection electrode DCE1.

The third source connection electrode SCE3 and the third drain connection electrode DCE3 may be placed on the fifth insulating layer INS5.

The ninth via electrode VA9 may penetrate the fifth insulating layer INS5 to connect the third source connection electrode SCE3 with the third source electrode SE3.

The tenth via electrode VA10 may penetrate the fifth insulating layer INS5 to connect the third drain connection electrode DCE3 with the third drain electrode DE3.

The third transistor TR3 may be connected to a light-emitting element LED. For example, the third drain electrode DE3 of the third transistor TR3 may be connected to a first electrode AND of the light-emitting element through a first connection electrode CNE1 on the sixth insulating layer INS6 and a second connection electrode CNE2 on a seventh insulating layer INS7. At this time, the first connection electrode CNE1 may be connected to the third drain connection electrode DCE3 through an eleventh via electrode VA11, and the second connection electrode CNE2 may be connected to the first connection electrode CNE1 through a twelfth via electrode VA12. In addition, the second connection electrode CNE2 may be connected to the first electrode AND through a thirteenth via electrode VA13.

The eleventh via electrode VA11 may penetrate the sixth insulating layer INS6 to connect the first connection electrode CNE1 with the third drain electrode DE3.

The twelfth via electrode VA12 may penetrate the seventh insulating layer INS7 to connect the second connection electrode CNE2 with the first connection electrode CNE1.

The thirteenth via electrode VA13 may penetrate the eighth insulating layer INS8 to connect the first electrode AND with the second connection electrode CNE2.

At least two of the first transistor TR1, the second transistor TR2 and the third transistor TR3 may have channel regions of different areas. For example, the first transistor TR1 of the driver circuit layer DCL may have a channel region having a larger area than that of a transistor (e.g., a pixel transistor) of the pixel circuit layer PCL. Specifically, a channel region may be defined by a channel width and a channel length. Accordingly, the channel width of the first channel region CH1 of the first transistor TR1 may be larger than the channel width of the second channel region CH2 of the second transistor TR2. In addition, the channel width of the first channel region CH1 of the first transistor TR1 may be larger than the channel width of the third channel region CH3 of the third transistor TR3. On the other hand, the channel length of the first channel region CH1, the channel length of the second channel region CH2, and the channel length of the third channel region CH3 may be equal to one another. As the channel width of the transistor of the driver circuit layer DCL is larger than the channel width of the pixel circuit layer PCL, even though the transistor of the driver circuit layer DCL is an oxide transistor rather than a metal-oxide-semiconductor field effect transistor (MOSFET), the operating speed of the driver circuit layer DCL can be relatively improved.

In addition, in a high-resolution display device 10, the transistors (e.g., transistors TR2 and TR3) of the pixel circuit layer PCL are densely integrated in the display area DAA, and thus they have a smaller size than the transistors of the driver circuit layer DCL. In this regard, the transistors of the pixel circuit layer PCL are formed as oxide transistors, not MOSFETs, so that it is possible to prevent or reduce the short-channel effects of the transistors in the display area DAA.

The display element layer EMTL may be located on the pixel circuit layer PCL in the display area DAA. The display element layer EML may include a pixel-defining layer PDL, the light-emitting element LED, and an encapsulation layer TFE.

The light-emitting element LED may be located on the third transistor TR3 in the display area DAA. For example, the light-emitting element LED may be located on the eighth insulating layer INS8. The light-emitting element LED may include a first electrode AND (e.g., an anode electrode), an emissive layer LE, and a second electrode CAT (e.g., a cathode electrode).

The first electrode AND may be located on the eighth insulating layer INS8 in the display area DAA. The first electrode AND may be connected to the second connection electrode CNE2 via the thirteenth via electrode VA13.

The pixel-defining layer PDL defining emission areas EA may be located on the first electrode AND. The pixel-defining layer PDL may be located on an edge of the first electrode AND.

The emissive layer LE may be arranged on the pixel-defining layer PDL. The emissive layer LE may be connected to the first electrode AND in the emission area EA of the display area DAA.

The second electrode CAT may be placed above the first electrode AND and the pixel-defining layer PDL.

The encapsulation layer TFE may be arranged on the second electrode CAT. The encapsulation layer TFE may be implemented as a composite film including an inorganic layer, an organic layer, and an inorganic layer. The encapsulation layer TFE can prevent or reduce contaminants such as moisture permeating into the emissive layer LE. A color filter may be placed on the encapsulation layer.

The display device 10 according to some embodiments may be applied to a variety of electronic devices. An electronic device according to some embodiments includes the display device 10 described above, and may further include a module or device having additional features in addition to the display device 10.

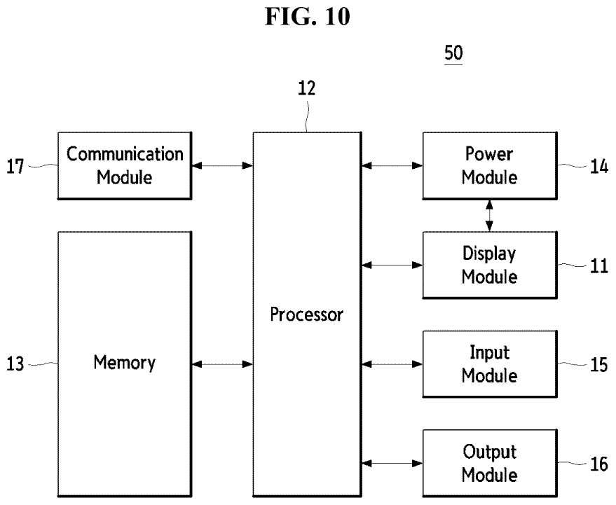

FIG. 10 is a block diagram of an electronic device according to some embodiments of the present disclosure. Referring to FIG. 10, an electronic device 50 according to some embodiments of the present disclosure may include a display module 11, a processor 12, a memory 13, and a power module 14. The electronic device 50 may further include an input module 14, a non-image output module 15, and/or a communication module 16.

The electronic device 50 may output various information in the form of images through the display module 11. When the processor 12 executes an application stored in the memory 13, image information provided by the application may be provided to the user through the display module 11. The power module 14 may include a power supply module such as a power adapter and a battery device, and a power conversion module that converts the power supplied by the power supply module to generate power required for the operation of the electronic device 50. The input module 14 may provide input information to the processor 12 and/or the display module 11. The non-image output module 15 may receive information other than images from the processor 12, such as sound, haptic and light information, and provide it to the user. The communication module 16 is responsible for transmitting and receiving information between the electronic device 50 and an external device, and may include a receiving unit and a transmitting unit.

At least one of the elements of the electronic device 50 described above may be included in the display devices according to the embodiments described above. In addition, some of the individual modules functioning as a single module may be included in the display device while some others may be provided separately from the display device. For example, the display device may include the display module 11, and the processor 12, the memory 13 and the power module 14 may be implemented as other devices inside the electronic device 11 instead of the display device.

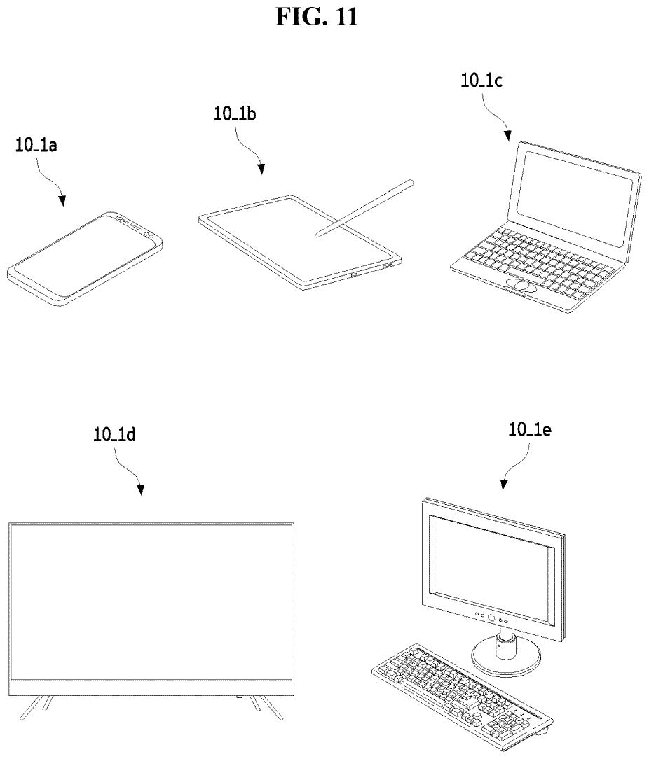

FIGS. 11, 12 and 13 are views showing electronic devices according to a variety of embodiments of the present disclosure. FIGS. 22 to 24 show examples of a variety of electronic devices employing the display devices 10 according to the embodiments.

FIG. 11 shows a smartphone 10_1a, a tablet PC 10_1b, a laptop computer 10_1c, a TV 10_1d, and a desktop monitor 10_1e as examples of the electronic devices.

The smartphone 10_1a may include an input module such as a touch sensor and a communication module in addition to a display module 11. The smartphone 10_1a may process information received through the communication module or other input modules and display the information through the display module of the display device.

The tablet PCs 10_1b, the laptop computer 10_1c, the TV 10_1d and the desktop monitor 10_1e may include display modules and input modules similar to the smartphone 10_1a, and may further include communication modules as desired.

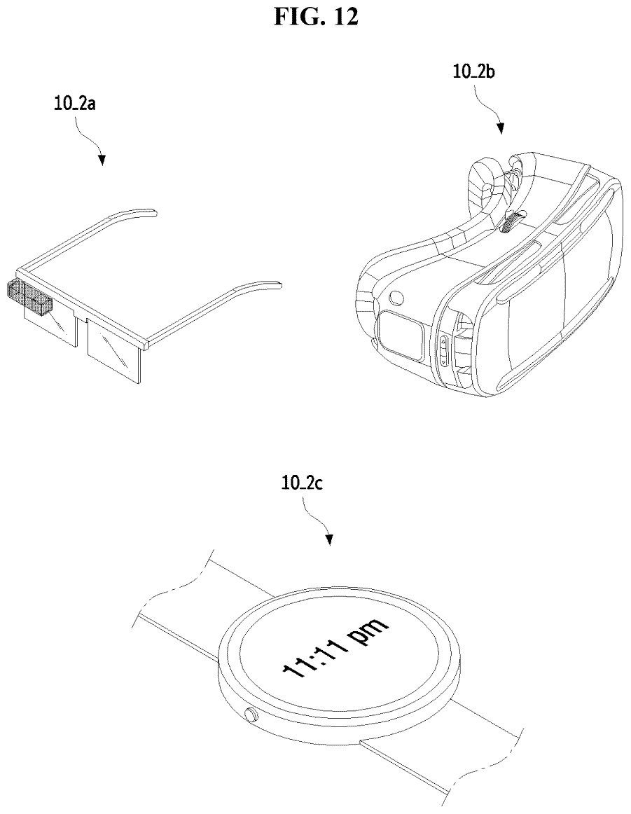

FIG. 12 shows examples of a wearable electronic device employing an electronic device including a display module. The wearable electronic devices may be smart glasses 10_2a, a head-mounted display 10_2b, a smart watch 10_2c, etc.

The smart glasses 10_2a and the head-mounted display 10_2b may include a display module that outputs display images, and a reflector that reflects the output display images and provides it to the user's eyes, thereby providing the user with images of virtual reality or augmented reality on the screen.

The smart watch 10_2c includes a biometric sensor as an input device, and may provide the user with biometric information recognized by the biometric sensor through the display module.

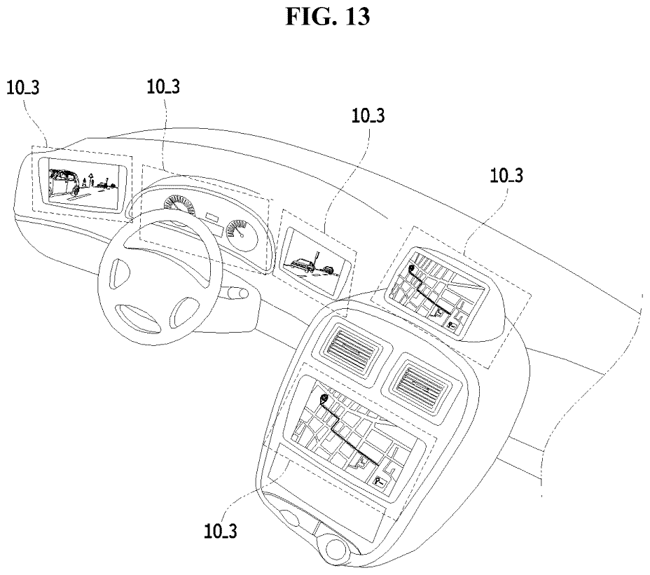

FIG. 13 shows an example of an electronic device including a display module applied to a vehicle. For example, an electronic device 10_3 may be applied to the instrument cluster, the center fascia, etc., of a vehicle, or may be applied to a center information display (CID) located at the dashboard of a vehicle, or may be used as a room mirror display on the behalf of the side mirrors of a vehicle.

In concluding the detailed description, those skilled in the art will appreciate that many variations and modifications can be made to the disclosed embodiments without departing from the spirit and scope of embodiments according to the present invention. Therefore, the disclosed embodiments of the invention are used in a generic and descriptive sense only and not for purposes of limitation.

What is claimed is:

1. A display device comprising:
a substrate having a display area and a non-display area; and
a driver circuit layer, a pixel circuit layer and a display element layer arranged on the substrate,
wherein the driver circuit layer is connected to a pixel circuit of the pixel circuit layer,
wherein the pixel circuit of the pixel circuit layer is connected to a light-emitting element of the display element layer, and
wherein the driver circuit layer, the pixel circuit layer and the display element layer are arranged on the display area of the substrate such that they overlap each other in a plan view.

2. The display device of claim 1, wherein the driver circuit layer comprises a first transistor, and the pixel circuit layer comprises a second transistor connected to the first transistor through a signal line.

3. The display device of claim 2, wherein each of the first transistor and the second transistor is an oxide semiconductor transistor.

4. The display device of claim 3, wherein the oxide semiconductor transistor comprises indium-gallium-zinc oxide or indium-gallium-zinc-tin oxide.

5. The display device of claim 2, wherein an area of a first channel region of the first transistor is different from an area of a second channel region of the second transistor.

6. The display device of claim 5, wherein the area of the first channel region is greater than the area of the second channel region.

7. The display device of claim 6, wherein a channel width of the first channel region is greater than a channel width of the second channel region.

8. The display device of claim 1, wherein the driver circuit layer is between the substrate and the pixel circuit layer.

9. The display device of claim 8, wherein the pixel circuit layer is between the driver circuit layer and the display element layer.

10. The display device of claim 1, wherein the pixel circuit layer is on the substrate and the driver circuit layer.

11. The display device of claim 10, wherein the driver circuit layer is between the pixel circuit layer and the display element layer.

12. The display device of claim 2, wherein the signal line comprises a scan line,
wherein the driver circuit layer comprises a plurality of scan drivers comprising the first transistor and connected to the scan line,
wherein the plurality of scan drivers is divided into a first scan group and a second scan group,
wherein the first scan group comprises a plurality of scan drivers arranged adjacent to each other along a diagonal direction, and
wherein the second scan group comprises a plurality of scan drivers arranged adjacent to each other along a diagonal direction.

13. The display device of claim 12, wherein a first scan driver of the first scan group is connected to a second scan driver of the second scan group that faces the first scan driver.

14. The display device of claim 13, further comprising:
a connection line connecting the first scan driver with the second scan driver.

15. The display device of claim 13, wherein the first scan driver and the second scan driver are connected to the scan line.

16. The display device of claim 12, wherein the driver circuit layer further comprises: a distribution group comprising a plurality of distribution circuits arranged adjacent to each other along a diagonal direction between the first scan group and the second scan group in the plan view.

17. An electronic device comprising:
a display device configured to display images, and
wherein the display device comprises:
a substrate having a display area and a non-display area; and
a driver circuit layer, a pixel circuit layer, and a display element layer on the substrate,
wherein the driver circuit layer is connected to a pixel circuit of the pixel circuit layer,
wherein the pixel circuit of the pixel circuit layer is connected to a light-emitting element of the display element layer, and
wherein the driver circuit layer, the pixel circuit layer and the display element layer are arranged on the display area of the substrate such that they overlap one another in a plan view.

18. The electronic device of claim 17, wherein the driver circuit layer comprises a first transistor, and the pixel circuit layer comprises a second transistor connected to the first transistor through a signal line.

19. The electronic device of claim 18, wherein each of the first transistor and the second transistor is an oxide semiconductor transistor.

20. The electronic device of claim 17, wherein the electronic device is one of a smartphone, a tablet PC, a laptop computer, a TV, a desktop monitor, smart glasses, a smart watch, a head-mounted display, or a display for vehicles.
